(19) United States
(12) Patent Application Publication
(10) Pub. No.: US 2023/0268421 A1
(43) Pub. Date: Aug. 24, 2023

(54) METHOD FOR AUTO-ALIGNED MANUFACTURING OF A TRENCH-GATE MOS TRANSISTOR, AND SHIELDED-GATE MOS TRANSISTOR

(71) Applicants: STMICROELECTRONICS S.r.l., Agrate Brianza (IT); STMICROELECTRONICS PTE LTD, Singapore (SG)

(72) Inventors: Vincenzo ENEA, Siracusa (IT); Voon Cheng NGWAN, Singapore (SG)

(73) Assignees: STMICROELECTRONICS S.r.l., Agrate Brianza (IT); STMICROELECTRONICS PTE LTD, Singapore (SG)

(21) Appl. No.: 18/168,509

(22) Filed: Feb. 13, 2023

(30) Foreign Application Priority Data
Feb. 21, 2022 (IT) 102022000003125

(51) Int. Cl. H01L 29/66; H01L 29/40; H01L 29/417; H01L 29/78; H01L 21/265; H01L 21/266

(52) U.S. Cl. CPC H01L 29/66734; H01L 29/407; H01L 29/41741; H01L 29/7813; H01L 21/26513; H01L 21/266; H01L 29/66727

(57) ABSTRACT

A MOS transistor of vertical-conduction, trench-gate, type, including a first and a second spacer adjacent to portions of a gate oxide of the trench-gate protruding from a semiconductor substrate, the first and second spacers being specular to one another with respect to an axis of symmetry; enriched P+ regions are formed by implanting dopant species within the body regions using the spacers as implant masks. The formation of symmetrical spacers makes it possible to form source, body and body-enriched regions that are auto-aligned with the gate electrode, overcoming the limitations of MOS transistors of the known type in which such regions are formed by means of photolithographic techniques (with a consequent risk of asymmetry).

### BACKGROUND

### Technical Field

The present disclosure relates to a method for manufacturing a metal oxide semiconductor (MOS) transistor, and to the corresponding MOS transistor.

### Description of the Related Art

As power metal-oxide-semiconductor field-effect (MOSFET) technology advances, cell pitch is reduced to reduce accordingly the overall die size to achieve better Rsil (Rsil is the on-state resistance of the device contributed by silicon, and normalized by area, measured as mΩ·mm²).

Fabricating devices with reduced cell pitch can be challenging, especially when it is limited by photolithography tool capability. Without a good alignment control, electrical parameters and device performances under unclamped inductive switching (UIS) conditions, as well as the threshold voltage (Vth) at which the device turns-on, can be compromised.

Therefore, a self-aligned contact approach (without the need for tight photolithography alignment control) can further improve UIS performance with reduced cell pitch.

UIS degradation can be caused by non-uniform or asymmetrical (with respect to active cell center) body well enrichment below the source/body junction. In fact, this situation can lead to current distribution issues during device switch-off, ultimately leading to UIS failures. This degradation can be amplified with the use of low doping of the body region to achieve a logic-level Vth.

The known solutions to improve UIS capability require to increase the body-well doping by performing an implant step through the source contact. In addition, a dedicated enrichment mask and following implant step, with a dedicated diffusion step (before contacts formations), is used to further increase body-well doping.

Known self-alignment methods are not easily integrated in a trench power MOSFET device, due to the complex process flow required. In fact, known solutions are limited by the mask alignment (both for manufacturing contacts or enrichment) with respect to the active cell center. As discussed above, mask create an asymmetrical doping distribution within the active cell which lead to an unbalanced current flow that degrade UIS performance, which can be worsened with the use of low doping body to achieve logic-level Vth.

Furthermore, with the known techniques, the cell pitch cannot be further and easily reduced. Advanced photolithography tools, such as a scanner, must be used, with an increase of costs and manufacturing complexity.

### BRIEF SUMMARY

The present disclosure is directed to a method for manufacturing a MOS transistor, and to the corresponding MOS transistor, to overcome the disadvantages of the known art.

The present disclosure is directed to a method for manufacturing a MOS transistor, the method comprising forming a trench in a semiconductor body, the trench having a first and a second side opposite to one another, filling the trench by forming, within the trench, a first oxide region, a conductive gate region that is electrically isolated from the semiconductor body by said first oxide region, and a second oxide region on the conductive gate region, removing portions of the semiconductor body adjacent to the first and second sides of the trench, forming a first and a second body region having a second type of conductivity, the first and second body region being adjacent to the respective first and second sides of the trench, and forming a first and a second source region having the first type of conductivity in the respective first and second body region.

The method includes forming first and second spacers adjacent to the first and second oxide regions and on the a first and a second source region, forming in the semiconductor body a first recess extending through said first source region and said first body region using said first spacer as an etching mask, forming in the semiconductor body a second recess extending through said second source region and said second body region using said second spacer as an etching mask, forming first and second enriched regions in electrical contact with the respective first and second body regions, including implanting dopant species of the second type of conductivity in the first and the second recess using said first and second spacers as implant masks, and forming a metal contact layer in the first and second recesses, to electrically contact the first and the second source region.

### BRIEF DESCRIPTION OF THE SEVERAL VIEWS OF THE DRAWINGS

For a better understanding of the present disclosure, preferred embodiments will now be described, purely by way of a non-limiting example, with reference to the drawings, in which

FIGS. 1-14 show in a lateral cross-sectional view (i.e., view on the XZ plane) steps for the manufacturing of a trench-gate MOS transistor according to one embodiment of the present disclosure.

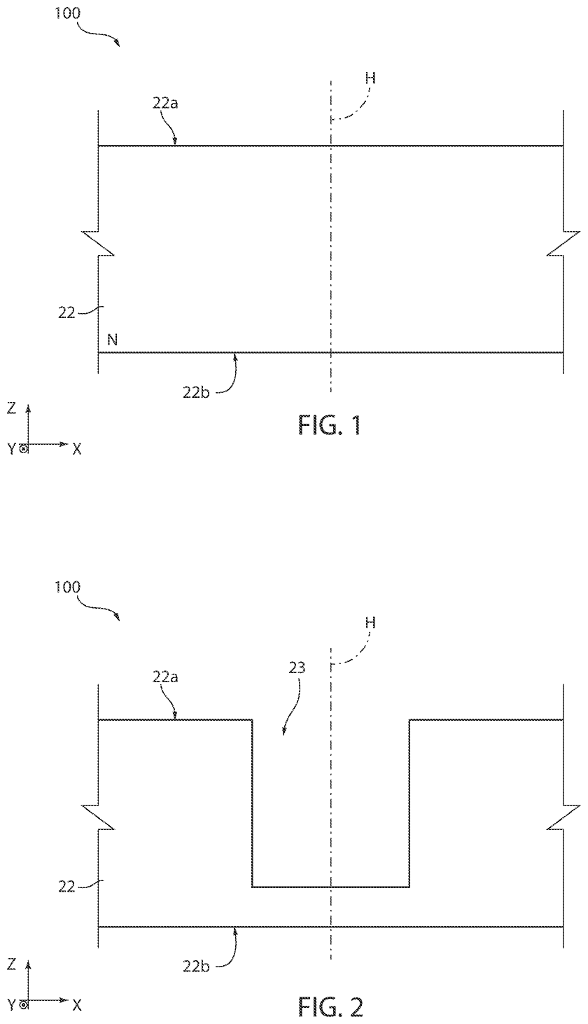

With reference to FIGS. 1-14, steps for the manufacture of a MOS transistor 21 according to one embodiment of the present disclosure are described (in particular, as apparent from the present description, a shielded-gate MOS transistor is disclosed). FIGS. 1-14 show, in particular, a lateral section of a portion of a wafer during subsequent manufacturing steps, in a triaxial reference system having orthogonal X, Y and Z axes. More in particular, FIGS. 1-14 illustrate a single cell 100 of the MOS transistor 21; in general, the MOS transistor 21 comprises a plurality of cells 100, arranged one alongside the other.

FIGS. 15-19 illustrate another embodiment for manufacturing a single cell 200 of a MOS transistor.

### DETAILED DESCRIPTION

With reference to FIG. 1, the wafer is provided including a semiconductor body 22 (which may include a substrate and one or more epitaxial layers grown on the substrate). The substrate and the epitaxial layers are of semiconductor material, for example Silicon, having a first conductivity type, in this case N type, and a doping concentration for example between 1·10¹⁶ and 6·10¹⁶ atoms/cm³; the semiconductor body 22 includes a first side 22a and a second side 22b parallel to the X axis. An axis of symmetry H of the cell 100, parallel to the Z axis, is also represented.

Then, FIG. 2, a trench 23 is etched in the semiconductor body 22, from the first side 22a toward the second side 22b (without reaching the second side 22b), with a depth along the Z axis of approximately 4-6 μm measured from the top side 22a. The trench 23 is symmetric with respect to the axis of symmetry H. According to one embodiment, the trench 23 is formed by means of photolithography and etching steps, which are in themselves known. For example, anisotropic etching (such as deep reactive-ion etching (DRIE) or reactive-ion etching (RIE) type) is used.

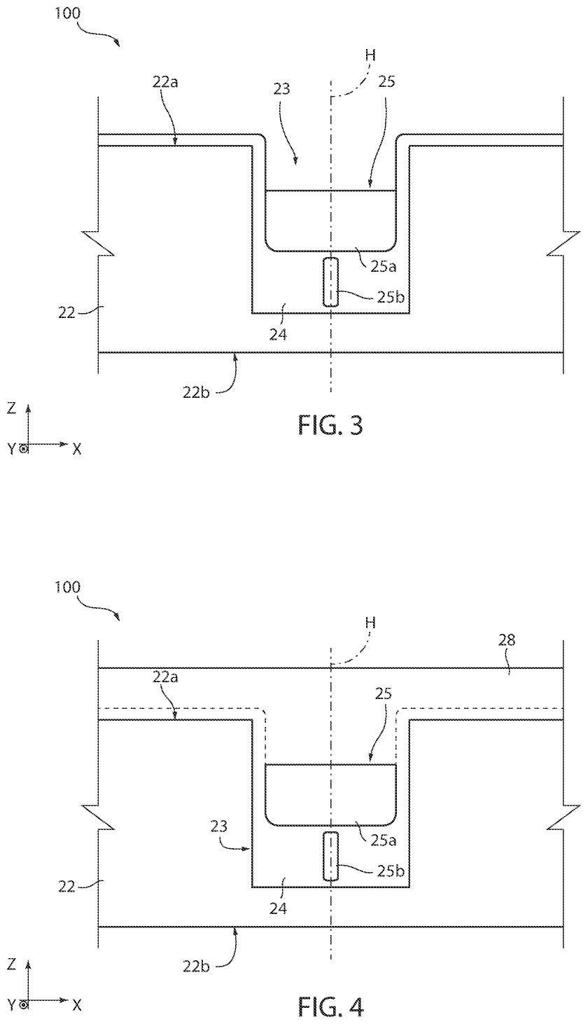

Then, FIG. 3, the trench 23 is partially filled with a field plate oxide layer 24, for example of Silicon Oxide, and with a gate oxide layer 26 over the field plate oxide layer 24. The field plate oxide layer 24 and the gate oxide layer 26 can be deposited or thermally grown. A conductive gate layer 25a, such as N-doped polysilicon, is further formed (e.g., deposited) in the trench 23 on the field plate oxide layer 24 and the gate oxide layer 26.

In one embodiment, the lower portions of the trench 23 (including its sidewalls and bottom wall) are completely covered by the field plate oxide layer 24. A buried field plate poly 25b can also be formed in the trench 23, below the conductive gate layer 25a, in a per se known way, and is used to reduce the electric field in the semiconductor body 22 near the trench 23 and to lower parasitic capacitance. The field plate 25b is buried within the field plate oxide layer 24. The field plate 25b is electrically isolated from the conductive gate layer 25a. This structure is also known as “shielded-gate” or “split-gate.” In the following, the conductive gate layer 25a is also named upper gate portion 25a (it is the actual transistor's gate electrode). The field plate 25b may be grounded.

It is noted that the upper gate portion 25a is recessed with respect to the first side 22a of a depth of about 200 nm measured from the first side 22a along the Z axis. This may be achieved by carrying out an etching step of the polysilicon after deposition, until the desired thickness of the upper gate portion 25a is achieved.

Then, FIG. 4, a step of growing or depositing an oxide layer 28 on the wafer, in particular on the gate oxide layer 26 and on the upper gate portion 25a, is carried out. For example, a low pressure chemical vapor deposition (LPCVD) step is performed to deposit Silicon Oxide, forming the oxide layer 28. The layers 26 and 28 (here, of the same material SiO₂) have a total thickness of about 500 nm measured from the first side 22a along the Z axis.

A chemical mechanical planarization (CMP) step is then carried out, to planarize the surface of the oxide layer 28 and to reduce its thickness down to about 300 nm.

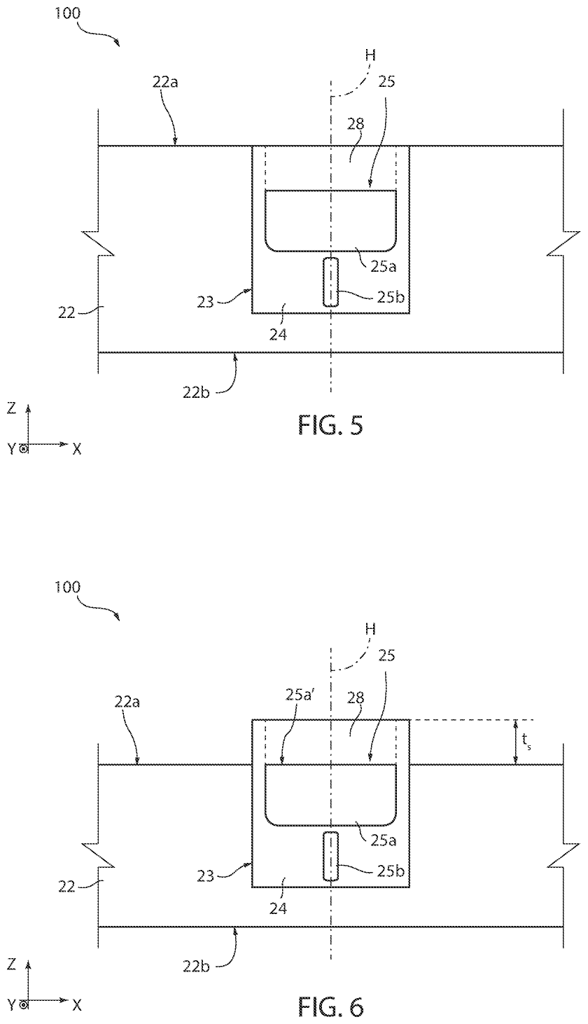

With reference to FIG. 5, a further etching step (in particular, an unmasked anisotropic etching) is carried out to remove the oxide layers 26 and 28 from the first side 22a of the semiconductor body 22, leaving portions of the oxide layers 26 and 28 extending within the trench 23. Therefore, the oxide layer 28 now extends within the trench 23 on the upper gate portion 25a, and has a top surface that is substantially coplanar with the first side 22a.

Then, FIG. 6, the semiconductor body 22 is etched vertically to the trench 23, in the mesa, reducing the thickness of the semiconductor body 22 of about t_{S}=180 nm along the Z axis. The first side 22a of the substrate, after this etching step, extends approximately at the same level, along the Z axis, as the top side 25a′ of the upper gate portion 25a. As a consequence of the etching of the semiconductor body 22, the gate oxide layer 26 and the oxide layer 28 protrude from the first side 22a of the semiconductor body 22.

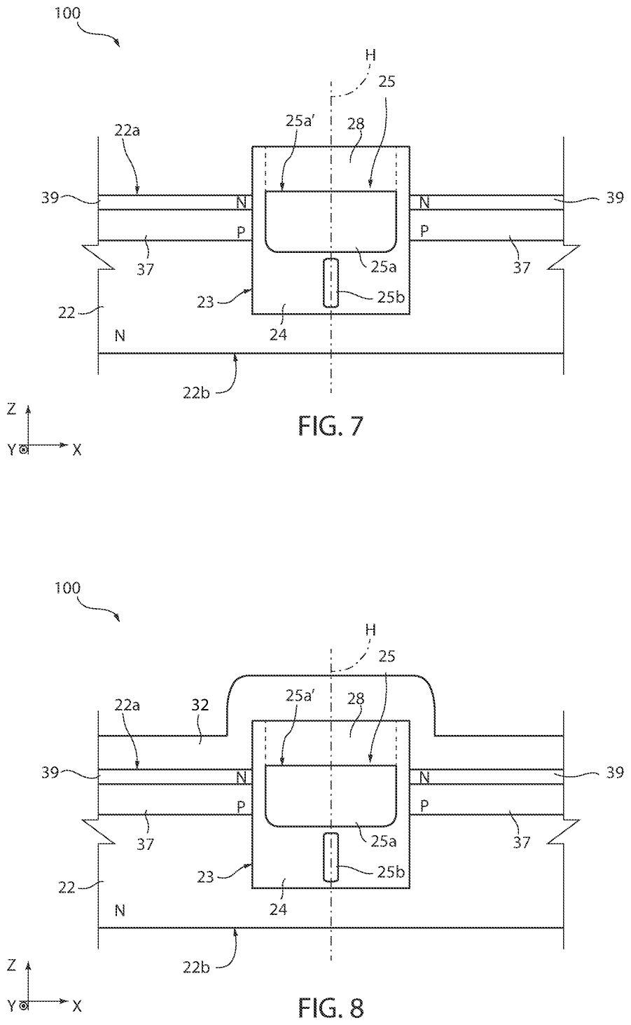

Then, FIG. 7, there follows a step of forming a body region 37 of the MOS device. This step includes an unmasked implant of doping species having a second type of conductivity different from the first type of conductivity (here, a P-type), for example Boron. In this way an implanted region which extends along and below the first side 22a of the semiconductor body 22, lateral and adjacent to the trench 23, is formed. The implant is for example performed using an implanting energy of 80 keV, achieving a concentration of doping species of approximately 1˜10¹⁸ atoms/cm³. A step of heat treatment at a temperature of approximately 1000° C. for approximately 30 seconds is carried out, in order to allow activation of the implanted species, forming the body region 37. For example, the body region 37 reaches a depth of approximately 0.5 μm along Z from the first side 22a of the semiconductor body 22. The region of the semiconductor body 22 proximate to the second side 22b, which is not reached by the diffusion of the doping species and is therefore outside the body region 37, forms a drain region of the semiconductor body 22.

Then, a step of forming a source region 39 of the MOS transistor is carried out. For this purpose doping species having the first type of conductivity (N-type), for example Arsenic, are implanted at the first side 22a of the semiconductor body 22, within the body region 37. Implantation is carried out using an implantation energy of for example 30 keV, achieving a concentration of doping species of the order of 1··10²⁰ atoms/cm³. A step of heat treatment at a temperature of approximately 1000° C. for approximately 30 seconds is carried out, to activate the implanted species, forming the source region 39. The source region 39 extends along the direction of the Z axis to a depth smaller than that of the body region 37. For example, the source region 39 reaches a depth of approximately less than 0.1 μm from the first side 22a of the semiconductor body 22.

Then, FIG. 8, a spacer layer 32, for example of oxide, such as Silicon Oxide, is formed on the wafer, covering the first side 22a of the semiconductor body 22, the gate oxide layer 26 and the oxide layer 28.

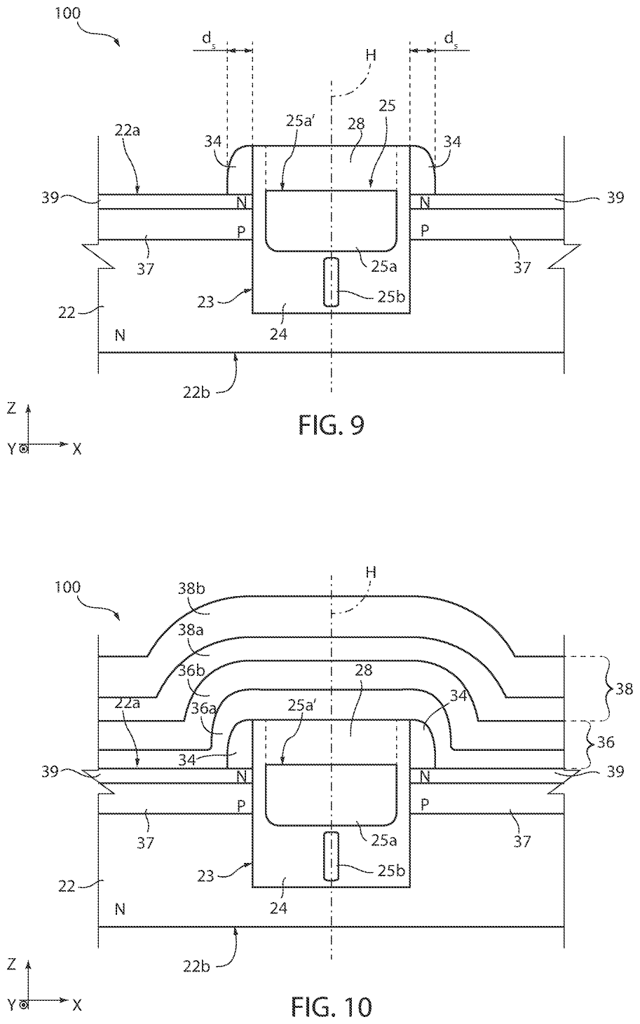

An etching step is carried out, FIG. 9, to partially remove the spacer layer 32. The etching is, in this case, an unmasked etching, in particular an anisotropic dry etching directed along the Z axis, configured to remove the spacer layer 32 on the horizontal (XY) plane, while preserving the spacer layer 32 on the vertical (XZ, YZ) planes. The etching is stopped when the spacer layer 32 is removed for its entire thickness on the first side 22a, with the exception of portions of the spacer layer 32 extending vertically (along the Z direction) along the lateral (vertical) sides of the gate oxide layer 26. Therefore, the spacers 34 are formed on the semiconductor body 22 next to, and adjacent to, the lateral sides of the gate oxide layer 26 previously formed in the trench 23 and protruding from the first side 22a of the semiconductor body 22. Each spacer 34 covers a portion of the first side 22a that is adjacent to the gate oxide layer 26. The spacers 34 thus formed are symmetrical with respect to symmetry axis H, have the same shape and also have a same base area (in other words, they cover a same respective area or same respective amount of semiconductor body 22 at the first side 22a).

The maximum extension d_{S} (along the X axis) of each spacer 34 is at the interface with the first side 22a; d_{S} measures at least 0.10 μm from the respective lateral side of the trench 23/gate oxide layer 26 to which each spacer 34 is adjacent.

Then, FIG. 10, a double layer 36 of insulating or dielectric material is formed, in particular by depositing a first sub-layer 36a of oxide (e.g., Silicon Oxide) with a thickness of about 20 nm, and a second sub-layer 36b of nitride (e.g., Silicon Nitride) over the first sub-layer 36a, with a thickness of about 30 nm. Deposition of the sub-layers 36a and 36b is carried out for example by LPCVD technique.

Then, a further deposition step is carried out to form a further bilayer 38 comprising a first sub-layer 38a of insulating material, such as silicon oxide, over the second sub-layer 36b, and having a thickness of about 200 nm, and a second sub-layer 38b over the first sub-layer 38a. The second sub-layer 38b is a pre-metal dielectric (PMD), for example of Borophosphosilicate glass (BPSG). The second sub-layer 38b has a thickness between 500 and 700 nm, in particular between 550 and 650 nm, more in particular of about 650 nm. The sub-layer 38b may be formed by subatmospheric chemical vapor deposition (SACVD).

The double layer 36 acts as a protection layer during the subsequent steps of forming and patterning the further bilayer 38.

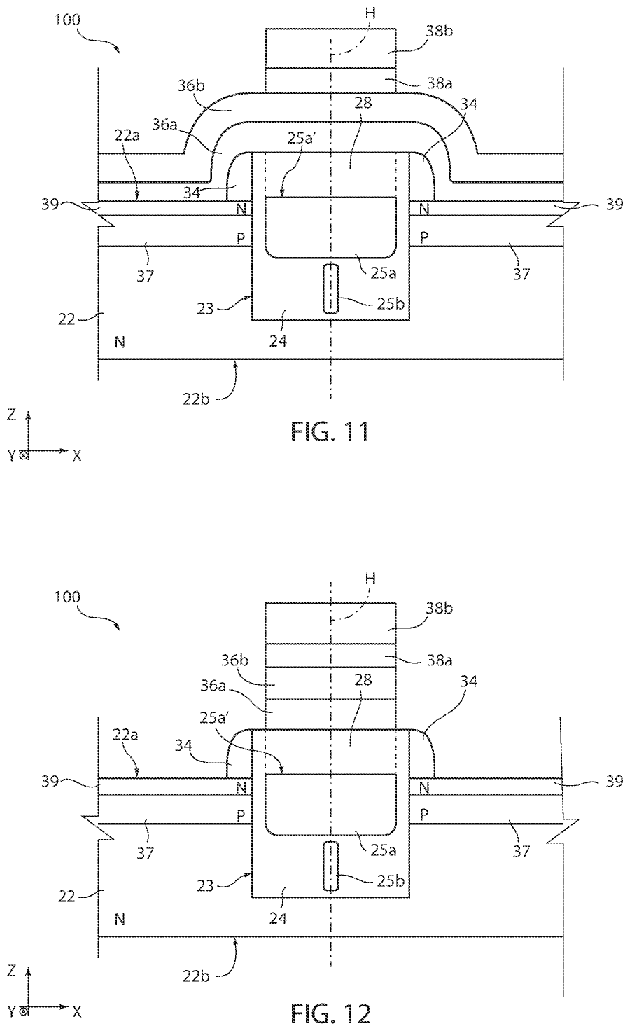

Then, FIG. 11, the bilayer 38 is patterned in order to maintain the bilayer 38 on the upper gate portion 25a (in particular substantially aligned, along the Z axis, with the upper gate portion 25a), and to remove the bilayer 38 from the remaining portions of the wafer. After patterning, the bilayer 38 does not cover the spacers 34, and therefore, in top plan view (i.e., view on the XY plane), it is contained between the spacers 34. To do so, a masked etching (or a photolithographic process) is performed, selectively removing portions of the bilayer 38 extending lateral to the upper gate portion 25a. The bilayer 38 is etched for its entire thickness where it has to be removed, using the second sub-layer 36b as an etching-stop layer. Accordingly, the chemical etchant is properly chosen to achieve such selectivity.

Then, FIG. 12, the second sub-layer 36b is removed from the wafer, with the exception of the portions of the second sub-layer 36b covered by the bilayer 38 (on the upper gate portion 25a, where the bilayer 38 is still present). Portions of the second sub-layer 36b may still cover in part the spacers 34, depending on the etching technique used (in particular, when the etching has a high directivity along the Z axis, portions of the second sub-layer 36b may remain along the vertical sides of the spacers 34).

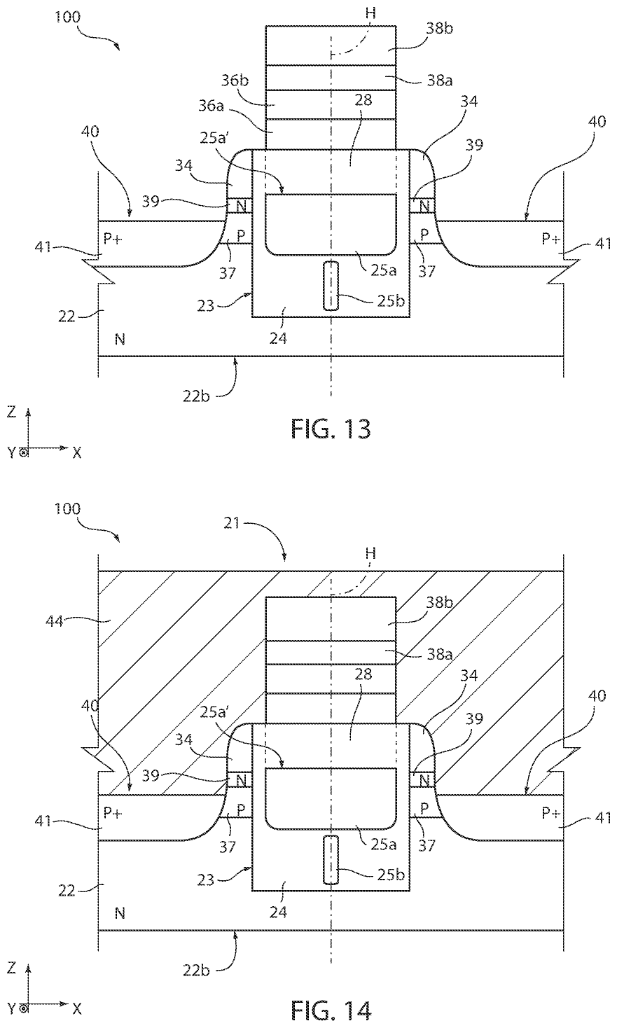

Then, FIG. 13, micro-trenches or recesses 40 are opened in the semiconductor body 22, lateral to the trench-gate 23 and in particular lateral to the spacers 34. More in particular, the spacers 34 act as an etching mask, so that during this etching step portions of the semiconductor body 22 not covered by the spacers 34 are selectively removed to form the trenches 40. Due to the symmetry of the spacers with respect to the axis H, also the recesses 40 are symmetric with respect to the axis H, and are auto-aligned. It is noted that, since the MOS transistor under manufacturing includes a plurality of cells 100 one next to the other, each recess 40 extends between, and is auto aligned to, two spacers 34. No photolithographic masks and related processes are therefore required.

The recesses 40 extend vertically from the first side 22a of the semiconductor body 22 through part of the semiconductor body 22, toward the second side 22b. The recesses 40 extend along the direction of the Z axis for a depth of approximately 300 nm. Each recess 40 is designed to extend over the entire thickness of the source region 39 and through part of the body region 37 of the device under fabrication, without reaching the drain region of the semiconductor body 22. The recess 40 is formed by anisotropic dry etching, thereby etching the Silicon material of the semiconductor body 22 selectively with respect to the material of the bilayer 38 (in particular sub-layer 38b) and the Silicon Oxide of the spacers 34. Because the spacers 34 are symmetrical with respect to the axis of symmetry H by design and the process described so far, not only are the recesses 40 are also symmetrical with respect to the axis of symmetry H, but also the source 39 and body regions 37.

Then, a step of forming enriched body regions 41 of the MOS transistor is carried out. For this purpose, doping species having the same type of conductivity as the body regions 39 (here, a P-type conductivity, for example Boron) are implanted. The implantation dose is higher than that of the body regions 39. The spacers 34 act as an implant mask which is auto-aligned with respect to the axis of symmetry H, such that the doping species penetrate in the region of the semiconductor body below the bottom wall of the recesses 40 (direction of implantation is along the Z axis). Implanting is for example carried out with an implanting energy of 40 to 80 keV, achieving a concentration of dopant species of approximately 1·10¹⁸ to 3·10¹⁹ atoms/cm³. Then, a step of heat treatment is performed, for example at a temperature of 1000° C. for a time of 30 seconds, sufficient to cause the activation of the implanted species. The enriched body regions 41 thus formed extend below each recess 40; in one embodiment the enriched body regions 41 extend as far as a depth equal to or greater than that of the respective body region (without however reaching the second side 22b of the semiconductor body 22). In a different embodiment, the enriched body regions 41 are completely contained within the respective body region 37 and extend as far as a depth lower than that of the respective body region 37.

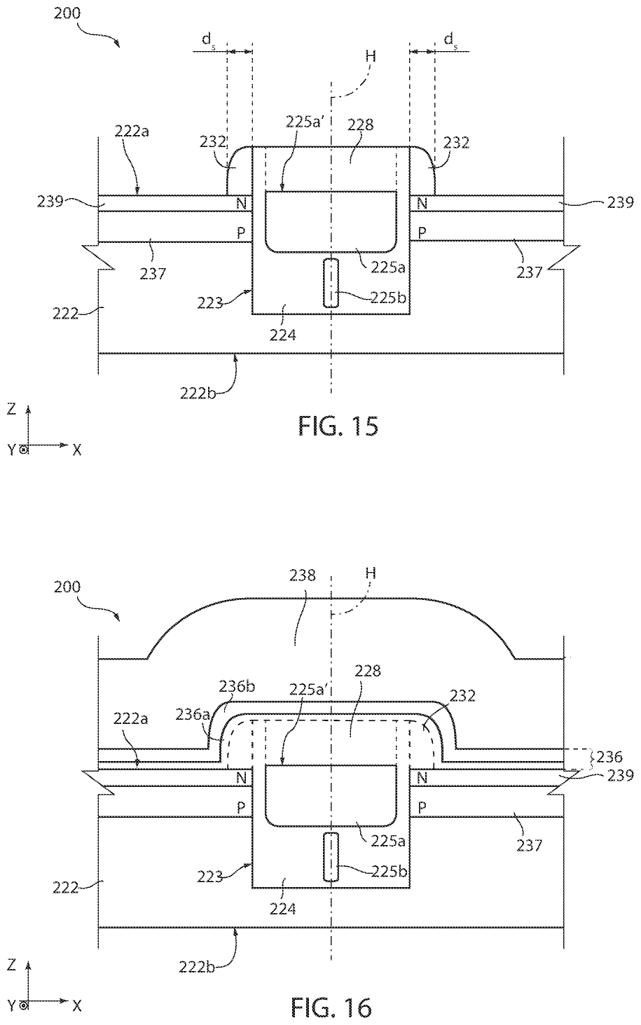

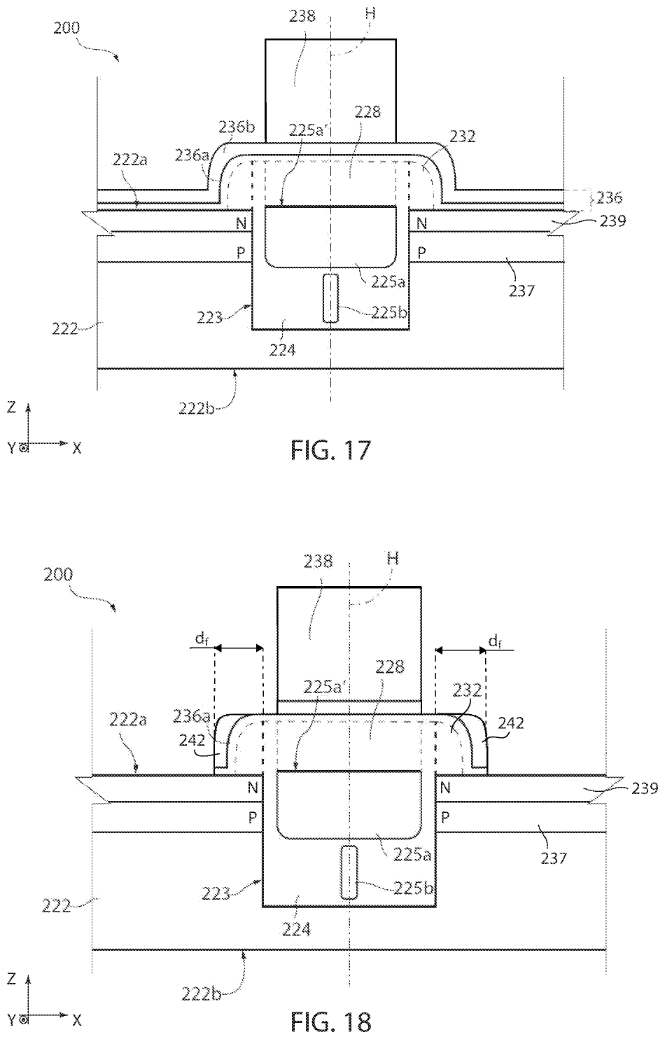

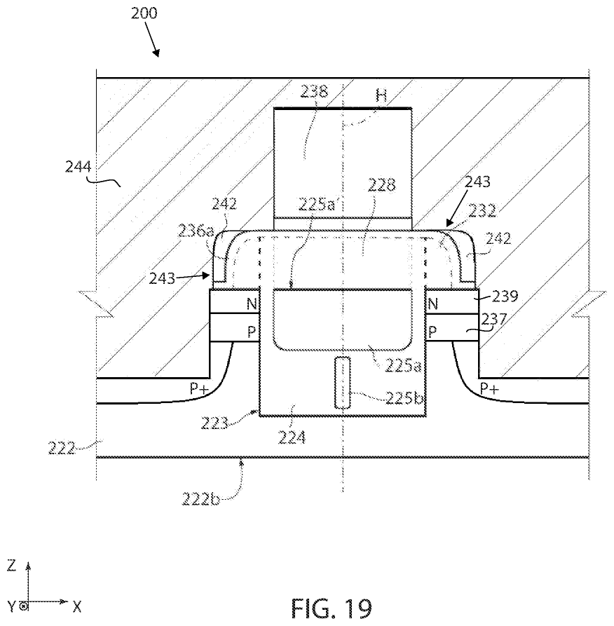

Then, FIG. 14, a conductive terminal 44 is formed, for example by depositing a metal material such as aluminum, tungsten and its barrier of titanium and titanium nitride on the wafer. The conductive terminal 44 completely fills the recesses 40 and is therefore in electrical contact with the semiconductor body 22 and in particular with the source regions 39, the enriched body regions 41 and the body regions 37 through the enriched body regions 41. The conductive terminal 44 forms a source electrode of the MOS transistor 21.

Thanks to the symmetry of the recesses 40, the enriched body regions 41 are symmetrical with respect to the axis of symmetry H and auto-aligned with respect to the trench gate and the regions where, during use, conductive channels will form.

In particular the distances along the X axis between the trench-gate 23 and the enriched body regions 41 are the same at both lateral sides of the trench-gate 23. In other words, the extension of the channel regions (as well as that of the source regions) is uniform in the entire cell 100 and symmetrical with respect to the axis of symmetry H.

FIGS. 15-19 illustrate another embodiment of manufacturing a metal oxide semiconductor (MOS) transistor. A semiconductor body 222 may be of silicon and have a first type of conductivity. A first side 222a of the semiconductor body 222 is etched to have a trench 223. The semiconductor body 222 has a second side 222b, opposite the first side 222a, that is substantially parallel to the X axis.

A field plate insulating layer 224, an upper gate portion 225a, a buried field plate poly 225b, and an insulating layer 228 are formed in the trench 223 in a similar manner as described above with respect to other embodiments. The upper gate portion 225a has a top side 225a′. The field plate insulating layer 224 and the insulating layer 228 may be of silicon dioxide. The upper gate portion 225a and buried field plate poly 225b may be of polysilicon.

A body region 237 having a second type of conductivity different from the first type of conductivity, for example, a P-type as shown in FIG. 15, is formed in the semiconductor body 222. The body region 237 is spaced more from the second side 222b of the semiconductor body 222 than the first side 222a of the semiconductor body 222. The body region 237 is aligned with the upper gate portion in along the X direction.

A source region 239 having the first type of conductivity, for example, N-type as shown in FIG. 15, is formed at the first side 222a of the semiconductor body 222 and within the body region 237. The body region 237 has a thickness in the Z direction greater than a thickness in the Z direction of the source region 239. The source region 239 and the body region 237 extend in the X direction to lateral walls of the trench 223. The body region 237 and source region 239 are formed in similar manners as described above with respect to other embodiments.

In FIG. 15, an insulating spacer layer 232 is deposited, for example via LPCVD, at lateral sides of the field plate insulating layer 224 and etched. The spacer layer 232 is formed adjacent to sidewalls of the insulating layer 228 that extend away from the surface 222a. The spacer layer 232 is also on the surface 222a. The spacer layer 232 has a dimension dₛ from the sidewalls of the insulating layer 228 to an outermost surface of the spacer layer 232. The spacer layer 232 may also be silicon dioxide.

In FIG. 16, a first insulating layer 236a, which may be of silicon dioxide is deposited, for example via LPCVD, on the first side 222a of the semiconductor body, the spacer layer 232, the field plate layer 224, and the insulating layer 228. Then, a nitride layer 236b, that may be of silicon nitride, is deposited, for example via LPCVD, on the silicon dioxide layer 236a. The nitride layer 236b has a thickness in the Z direction greater than a thickness in the Z direction of the silicon dioxide layer 236a. The boundaries of the spacer layer 232 and the first insulating layer are shown in dash as they are the same material in some embodiments.

A second insulating layer 238 is deposited, for example via a sub-atmospheric chemical vapor deposition (SACVD), over the nitride layer 236b. The second insulating layer 238 has a thickness that is greater than a sum of the thickness of the first insulating layer 236a and the nitride layer 236b along the Z direction.

Then, in FIG. 17, the second oxide layer 238 is etched, for example using a contact mask, which is removed, for example via resist removal, after etching is complete. The resulting etched second oxide layer 238 is over the insulating layer 228 and is no longer over the field plate oxide layer 224 or the oxide spacer layer 232. It is noted that the second oxide layer 238 may be formed in a single process or may be formed in two steps, such as an SACVD step followed by a borophosphosilicate glass (BPSG) step. The SACVD step may form a 2,000 angstrom layer. The BPSG step may form a 6,500 angstrom layer.

Next, the nitride layer 236b and the first insulating layer 236a are etched in FIG. 18. The nitride layer 236b is etched to form a spacer nitride 242. Portions of the first surface 222a of the semiconductor body 222 and the first insulating layer 236a are exposed. A combined spacer includes spacer layer 232 and spacer nitride 242. The combined spacer extends from the side wall of the insulating layer 228 to an outer edge of the spacer nitride 242. The combined spacer has a final dimension d_{f}. This dimension d_{f} is greater than the dimension dₛ.

A trench is etched in the semiconductor body 222 in FIG. 19 and a front metal 244 is deposited. The trench extends into the semiconductor body 222 to an intermediate location between the first surface 222a and a bottom surface or area of the field plate layer 224. A channel region is formed in the portion of the semiconductor body 222 that is under the combined sidewall and adjacent to the field plate layer 224. The spacer nitride 242 controls a dimension of the combined spacer to manage and control a dimension in the X direction of the channel formed in the semiconductor body.

A P+ region may be formed in the remaining semiconductor body 222 with a variety of techniques. The P+ region extends from the body region 237 in the portion of the semiconductor body that is adjacent to the field plate layer 224.

The advantages of the present disclosure are discussed below.

In the process of manufacturing the MOS transistor the formation of spacers 34, which are symmetrical with respect to the axis of symmetry H, makes it possible to form source, body and body-enriched regions that are auto-aligned with the gate electrode, overcoming the limitations of MOS transistors of the known type in which such regions are formed by means of photolithographic techniques (with a consequent risk of asymmetry).

Furthermore, the auto-alignment of the above-mentioned regions makes it possible to reduce the electrical resistance of the portion of the body region through which the turn-off current passes under unclamped inductive switching (UIS) conditions.

It is thus possible to maximize the capacity of the MOS transistor to control high currents under unclamped inductive switching conditions.

Further to the above, the present disclosure allows the use of a pre-metal dielectric (layer 38b) as thick as needed (i.e., for sustaining high voltages), still maintaining a contact opening well controlled in terms of distance and alignment. This is obtained not only through the formation of thin spacers 34, which ensure a tight process control on silicon contact, but also by the introduction of layers 36a and 36b. The latter act as a whole as a protection layer 36 during the following deposition, masking, and etching steps related to the formation of the thick layer 38. The thick layer 38 gives to the whole device structure a high level of electrical insulation (needed for higher voltage device) and high reliability performances (lower average electric field within it). By this way it is possible to use a lithographic mask to open and etch the layer 38 and finally remove the protection layer 36 without impact on silicon contact control or spread and its alignment.

Moreover, the present disclosure enables logic-level Vth technology using lower body dose without the adverse effect from body enrichment misalignment that impacts the Vth.

Balanced current flow distribution during switch off operation is also achieved. Higher UIS capabilities are therefore achieved.

Wider contacts are allowed due to improved contact alignment (no alignment margin is needed).

Finally, the present disclosure enables a pitch reduction for better on-state resistance contributed by Silicon and normalized by area (Rsil).

Finally, it is clear that modifications and variants may be made to the disclosure described and illustrated here without thereby going beyond the protective scope of the present disclosure.

For example, the trench 23 has been described having vertical sidewalls; according to the process used for manufacturing the trench 23, it may also have inclined sidewalls, in particular sidewalls forming, in the cross-section view of FIGS. 1-14, an obtuse angle (>90°) at the intersection with the front side 22a (in this case, the trench 23 has a truncated V-like shape in a side view, or a truncated reversed-pyramid shape). The teaching of the present disclosure applies analogously also in case of sidewalls of the trench 23 not perfectly parallel to the Z axis.

In particular, the present disclosure can be applied to any type of vertically-conducting device with a trench gate, such as a vertical, double-diffused, metal-oxide semiconductor (VDMOS) transistor, or a trench-based power MOSFET device.

An embodiment includes, before forming the recess 40, forming the first sub-layer 36a, of a first dielectric material, on the oxide layer 28 on the first and second spacers 34 and on the source region 39. Then, forming the second sub-layer 36b, of a second dielectric material different from the first dielectric material, on the first sub-layer 36a. Then, forming the third sub-layer 38a, of a third dielectric material different from the second dielectric material, on the second sub-layer 36b, forming a fourth sub-layer 38b, of a fourth dielectric material different from the third dielectric material, on the third sub-layer 38a. Patterning the third and the fourth sub-layers 38a, 38b to form respective third and fourth sub-layer 38a, 38b sub-regions above the oxide layer 28 between the first and second spacers 34, and patterning the first and the second sub-layers 36a, 36b using the third and fourth sub-layer 38a, 38b sub-regions as patterning masks, to form respective first and second sub-layer 36a, 36b sub-regions between the oxide layer 28 and the third and fourth sub-layer 38a, 38b sub-regions, thus exposing at least in part the first and second spacers 34. For example, the first dielectric material may be an oxide of semiconductor material, and the second dielectric material may be a nitride of said semiconductor material. The fourth sub-layer 38b may be a pre-metal dielectric (PMD). The fourth dielectric material may be borophosphosilicate glass (BPSG). The third dielectric material may be an oxide of said semiconductor material.

Another embodiment includes, when patterning the third and the fourth sub-layers 38a, 38b, performing a masked etching to selectively remove portions of the third and fourth sub-layers 38a, 38b extending lateral to the oxide layer 28, and etching patterning the third and fourth sub-layers 38a, 38b for their entire thickness laterally to the oxide layer 28, the second sub-layer 36b being an etching-stop layer.

An embodiment includes the first sub-layer 36a on and aligned to the oxide layer 28, the second sub-layer 36b on and aligned to the first sub-layer 36a, the third sub-layer 38a on and aligned to the second sub-layer 36b, and the fourth sub-layer 38b on and aligned to the third sub-layer 38a. The first sub-layer 36a is aligned to the oxide layer 28 along the Z direction, orthogonal to the first and second side 22a, 22b of the semiconductor body 22, the second sub-layer 36b is aligned to the first sub-layer 36a along said Z direction, the third sub-layer 38a is aligned to the second sub-layer 36b along said Z direction, and the fourth sub-layer 38b is aligned to the third sub-layer 38a along said Z direction.

A method for manufacturing a MOS transistor (21), may be summarized as including the steps of providing a semiconductor body (22) having a first and a second side (22a, 22b) opposite to one another and a first type of conductivity (N); forming a trench (23) in the semiconductor body (22) at the first side (22a), the trench (23) having a first and a second lateral side extending symmetric to one another with respect to an axis of symmetry (H) orthogonal to the first and second side (22a, 22b); filling the trench (23) by forming, within the trench (23), an oxide region (24, 26), a conductive gate region (25a) that is electrically isolated from the semiconductor body (22) by said oxide region (24, 26), and a top oxide region (28) on the conductive gate region (25a); forming a first and a second body region (37) having a second type of conductivity (P) facing the first side (22a) of the semiconductor body (22) and adjacent to the first and respectively the second lateral sides of the trench (23); forming a first and a second source region (39) having the first type of conductivity (N) within the first and respectively second body region (37) and facing the first side (22a); and forming a drain electrode at the second side (22b), characterized by further including the steps of: after filling the trench (23) and before forming the first second body regions (37) and the first and second source regions (39), reducing a thickness of the semiconductor body (22) by removing, at the first side (22a), portions of the semiconductor body (22) adjacent to the first and the second lateral sides of the trench (23), so that the oxide region (24, 26) and of the top oxide region (28) protrude in part from the semiconductor body (22) at the first side (22a); after forming the first second body regions (37) and the first and second source regions (39), forming a first and a second spacer (34) adjacent to the oxide region (24, 26) protruding from the semiconductor body (22) at the first side (22a), the first and second spacers (34) being specular to one another with respect to said axis of symmetry (H); forming, in the semiconductor body (22), a first recess (40) extending through said first source region (39) and said first body region (37) using said first spacer (34) as an etching mask; forming, in the semiconductor body (22), a second recess (40) extending through said second source region (39) and said second body region (37) using said second spacer (34) as an etching mask; implanting dopant species of the second type of conductivity (P) at a bottom side of the first and the second recess (40) using said first and second spacers (34) as implant mask, to form a respective first and second enriched regions (41) in electrical contact with the first and respectively second body regions (37); and forming a metal contact layer (44) within the first and second recesses (40), to electrically contact the first and the second source region (39).

The step of forming the first and second spacers may include the steps of forming a spacer layer (32) of insulating or dielectric material on the first side (22a), on the oxide region (24, 26) protruding from the semiconductor body (22) and on the top oxide region (28); and performing an unmasked etching step designed to remove portions of the spacer layer (32) extending parallel to the first side (22a).

The unmasked etching step may include performing an anisotropic dry etching step configured to remove portions of the spacer layer (32) extending parallel to the first side (22a) and to preserve further portions of the spacer layer (32) extending along the oxide region (24, 26) orthogonal to the first side (22a).

The unmasked etching step may be stopped when the spacer layer (32) extending parallel to the first side (22a) is completely removed.

The step of filling the trench (23) may include the further step of forming, within the trench (23) and before forming the conductive gate region (25a), a field plate (25b) of electrically conductive material that is electrically isolated from the semiconductor body (22) by said oxide region (24, 26).

The first and second spacers (34) may cover a same respective amount of surface region of the first side (22a).

A MOS transistor (21), may be summarized as including a semiconductor body (22) having a first and a second side (22a, 22b) opposite to one another and a first type of conductivity (N); a trench (23) in the semiconductor body (22) at the first side (22a), the trench (23) having a first and a second lateral side extending symmetric to one another with respect to an axis of symmetry (H) orthogonal to the first and second side (22a, 22b); an oxide region (24, 26) covering bottom and lateral walls of said trench (23); a conductive gate region (25a) in said trench (23) on the oxide region (24, 26) in such a way to be electrically isolated from the semiconductor body (22) by said oxide region (24, 26); a top oxide region (28) in the trench (23) on the conductive gate region (25a); a first and a second body region (37) having a second type of conductivity (P) facing the first side (22a) of the semiconductor body (22) and adjacent to the first and respectively the second lateral sides of the trench (23); a first and a second source region (39) having the first type of conductivity (N) within the first and respectively second body region (37) and facing the first side (22a); and a drain electrode at the second side (22b), wherein: the oxide region (24, 26) and of the top oxide region (28) protrude in part from the semiconductor body (22) at the first side (22a), the MOS transistor further including a first and a second spacer (34) adjacent to the oxide region (24, 26) protruding from the semiconductor body (22), the first and second spacers (34) being specular to one another with respect to said axis of symmetry (H); a first recess (40) in the semiconductor body (22), extending through said first source region (39) and said first body region (37) adjacent to said first spacer (34); a second recess (40) in the semiconductor body (22) extending through said second source region (39) and said second body region (37) adjacent to said second spacer (34); a first and a second enriched region (41), of the second type of conductivity (P), extending a bottom side of the first and respectively second recess (40), in electrical contact with the first and respectively second body regions (37); and a metal contact layer (44) within the first and second recesses (40) in electrical contact with the first and the second source region (39).

The first and second spacers (34) may be of insulating or dielectric material.

The MOS transistor may further include a field plate (25b) of electrically conductive material in the trench (23) buried in said oxide region (24, 26).

The first and second spacers (34) may cover a same respective amount of surface region of the first side (22a).

The MOS transistor may be of a vertical-conduction type, or a VDMOS transistor.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a MOS transistor, comprising:
forming a trench in a semiconductor body, the trench having a first and a second side opposite to one another;
filling the trench by forming, within the trench, a first oxide region, a conductive gate region that is electrically isolated from the semiconductor body by said first oxide region, and a second oxide region on the conductive gate region;
removing portions of the semiconductor body adjacent to the first and second sides of the trench;
forming a first and a second body region having a second type of conductivity, the first and second body region being adjacent to the respective first and second sides of the trench;
forming a first and a second source region having the first type of conductivity in the respective first and second body region; forming first and second spacers adjacent to the first and second oxide regions and on the a first and a second source region;
forming, in the semiconductor body, a first recess extending through said first source region and said first body region using said first spacer as an etching mask;
forming, in the semiconductor body, a second recess extending through said second source region and said second body region using said second spacer as an etching mask;
forming first and second enriched regions in electrical contact with the respective first and second body regions, forming includes implanting dopant species of the second type of conductivity in the first and the second recess using said first and second spacers as implant masks; and
forming a metal contact layer in the first and second recesses, to electrically contact the first and the second source region.

2. The method of claim 1, wherein the forming the first and second spacers includes:
forming a spacer layer of insulating material, on the first and second oxide regions protruding from the semiconductor body; and
performing an unmasked etching removing portions of the spacer layer.

3. The method of claim 2, wherein the unmasked etching includes performing an anisotropic dry etching removing portions of the spacer layer on the semiconductor body and preserving further portions of the spacer layer adjacent the first oxide region.

4. The method of claim 3, wherein the unmasked etching is stopped when the portions of the spacer layer on the semiconductor body is completely removed.

5. The method of claim 1, wherein the filling the trench includes forming, before forming the conductive gate region, a field plate of electrically conductive material that is electrically isolated from the semiconductor body by said first oxide region.

6. The method of claim 1, wherein the first and second spacers cover a same respective amount of surface region of the semiconductor body.

7. A metal oxide semiconductor (MOS) transistor, comprising:
a semiconductor body having a first and a second side opposite to one another and a first type of conductivity;
a trench in the semiconductor body at the first side, the trench having a first and a second side opposite to one another, the first and second sides of the trench being transverse to the first side of the semiconductor body and extending toward the second side of the semiconductor body;
a first oxide region in the trench on the first and second sides of said trench;
a conductive gate region in said trench on the first oxide region, the conductive gate region being electrically isolated from the semiconductor body by said first oxide region;
a second oxide region in the trench on the conductive gate region;
a first and a second body region having a second type of conductivity adjacent to the respective first and second sides of the trench, the first and second body region are closer to the first side than the second side of the semiconductor body;
a first and a second source region having the first type of conductivity within the respective first and second body region; and
a drain electrode at the second side of the semiconductor body;
wherein portions of the first and second oxide regions protrude from the first side of the semiconductor body;
first and second spacers adjacent to the portions of the first oxide region protruding from the first side of the semiconductor body, the first and second spacers;
a first recess in the semiconductor body extending through said first source region and said first body region adjacent to said first spacer;
a second recess in the semiconductor body extending through said second source region and said second body region adjacent to said second spacer;
a first and a second enriched region, of the second type of conductivity with a different doping concentration than the first and second body regions, the first and second enriched region, in the respective first and second recess, the first and second enriched region being in electrical contact with the respective first and second body regions; and
a metal contact layer in the first and second recesses in electrical contact with the first and the second source region.

8. The MOS transistor of claim 7, wherein the first and second spacers are of insulating material.

9. The MOS transistor of claim 7, comprising a field plate of electrically conductive material in the trench buried in said first oxide region.

10. The MOS transistor of claim 8, wherein the first and second spacers cover a same respective amount of surface region of the first side of the semiconductor body.

11. A method, comprising:
forming a trench in a first side of semiconductor body, the trench extending toward a second side of the semiconductor body opposite the first side;
forming a first oxide layer on the first side of the semiconductor body and in the trench;
forming a conductive gate region on the first oxide layer in the trench;
forming a second oxide layer on the conductive gate region, a surface of the second oxide layer being substantially coplanar with the first side of the semiconductor body;
forming a protrusion extending from the first side of the semiconductor body, the protrusion having portions of the first and second oxide layers;
forming first and second body regions on the first side of the semiconductor body, the first and second body regions being around the protrusion;
forming first and second source regions on the respective first and second body regions;
forming first and second spacers on the respective first and second source regions, the first and second spacers adjacent the protrusion, wherein forming the first and second spacers includes:
forming a spacer layer on the first side of the semiconductor body; and
removing portions of the spacer layer to expose portions of the first and second source regions, the first and second spacers each covering a surface area of the first side of the semiconductor body that is substantially the same to each other;
forming first and second enriched regions electrically coupled with the respective first and second body regions; and
forming a metal contact layer on the protrusion and first and second enriched regions.

12. The method according to claim 11, wherein forming the first and second body regions includes implanting a first doping species in the first side of the semiconductor body and heat treating to activate the first doping species.

13. The method according to claim 12, wherein forming the first and second source regions includes implanting a second doping species in the first and second body regions and heat treating to activate the second doping species.

14. The method according to claim 13, wherein the first and second doping species have different types of conductivity from each other.

15. The method according to claim 14, comprising forming a drain region in second side of the semiconductor body.

16. The method according to claim 11, comprising:
forming a double insulating layer on the first and second spacers and the exposed portions of the first and second source regions; and
patterning the double insulating layer to remove portions on the first and second spacers and the first oxide layer.

17. The method according to claim 16, comprising forming first and second recesses in the first side of the semiconductor body, the first and second recesses extend from the respective first and second spacers through the respective first and second body and source regions.

18. A device, comprising:
a substrate having a first surface;
a first trench in the substrate;
a first dielectric layer in the first trench;
a first gate portion in the first dielectric layer;
a second dielectric layer on the first gate portion, the second dielectric layer extending past the first surface of the substrate;
a combined spacer on the first surface and adjacent to the second dielectric layer, the combined substrate having a first silicon dioxide portion and a second silicon nitride portion, the nitride portion being spaced from the second dielectric layer by the first silicon dioxide portion;
a second trench in the substrate; and
a third trench in the substrate, the first trench being between the second trench and the third trench.

19. The device of claim 18, wherein a second gate portion in the first dielectric layer, the second gate portion between the first gate portion and the substrate.

20. The device of claim 18, comprising a third dielectric layer on the second dielectric layer, a silicon nitride portion being between the third dielectric layer and the second dielectric layer.
